(19) United States
(12) Patent Application Publication
(10) Pub. No.: US 2008/0268619 A1
(43) Pub. Date: Oct. 30, 2008

(54) Wafer dividing method

(75) Inventor: Masaru NAKAMURA, Tokyo (JP)

Correspondence Address: SMITH, GAMBRELL & RUSSELL, 1130 CONNECTICUT AVENUE, N.W., SUITE 1130, WASHINGTON, DC, 20036, US

(73) Assignee: Disco Corporation

(21) Appl. No.: 12/081,937

(22) Filed: Apr. 23, 2008

(30) Foreign Application Priority Data
Apr. 26, 2007 (JP) 2007-117040

(51) Int. Cl. H01L 21/78

(52) U.S. Cl. 438/463; 257/E21.599

(57) ABSTRACT

A method of dividing a wafer having devices which are formed in a plurality of areas sectioned by a plurality of streets formed in a lattice pattern on the front surface of a substrate and a protective film which covers the front surfaces of the devices into individual devices along the streets, comprising the steps of:

applying a laser beam of a wavelength having absorptivity for the protective film to the protective film from the front surface side of the wafer along the streets to form grooves so as to divide the protective film along the streets;

applying a laser beam of a wavelength having permeability for the substrate to the wafer which has undergone the above protective film dividing step along the streets with its focal point set to positions below the grooves so as to form deteriorated layers in the inside of the substrate along the streets; and

applying external force to the wafer in which the protective film has been divided along the streets and the deteriorated layers have been formed in the inside of the substrate along the streets to divide the wafer along the streets.

### FIELD OF THE INVENTION

The present invention relates to a method of dividing a wafer having a plurality of streets which are formed in a lattice pattern on the front surface and devices which are formed in a plurality of areas sectioned by the plurality of streets along the streets.

### DESCRIPTION OF THE PRIOR ART

In the production process of a semiconductor device, a plurality of areas are sectioned by dividing lines called “streets” arranged in a lattice pattern on the front surface of a substantially disk-like semiconductor wafer, and a device such as IC, LSI, liquid crystal driver or flash memory is formed in each of the sectioned areas. Individual devices are manufactured by cutting this semiconductor wafer along the streets to divide it into the device formed areas.

Cutting along the streets of the above wafer is generally carried out by a cutting machine called “dicer”. This cutting machine comprises a chuck table for holding a workpiece such as a wafer or the like, a cutting means having a cutting blade for cutting the workpiece such as a wafer or the like held on the chuck table, and a feed means for relatively-moving the chuck table and the cutting means and cuts the workpiece with the cutting blade while cutting water is supplied to a portion to be cut.

However, since a wafer having devices such micro-electro-mechanical systems (MEMS) disfavors water, there is a problem that the quality of each device is deteriorated when the wafer is cut by the cutting machine while cutting water is supplied.

As a means of dry dividing a plate-like workpiece such as a semiconductor wafer without using a fluid such as cutting water, JP-A 10-305420 discloses a method in which a pulsed laser beam of a wavelength having absorptivity for the wafer is applied along streets formed on the wafer to form a groove in the wafer along the streets and the wafer is divided along the grooves.

However, when the groove is formed by applying a pulsed laser beam to the wafer made from silicon, debris is produced and adheres to the surfaces of devices such as micro-electro-mechanical systems (MEMS), thereby reducing the quality of each device.

As a means of dry dividing a plate-like workpiece such as a semiconductor wafer without using a fluid such as cutting water, a laser processing method in which a pulsed laser beam of a wavelength having permeability for the workpiece is applied with its focal point set to the inside of the area to be divided is tried and disclosed by Japanese Patent No. 3408805. In the dividing method making use of this laser processing technique, the workpiece is divided by applying a pulsed laser beam of a wavelength having permeability for the workpiece to one side of the workpiece with its focal point set to the inside to continuously form a deteriorated layer along the streets in the inside of the workpiece and applying external force along the streets whose strength has been reduced by the formation of the deteriorated layers. This method makes it possible to reduce the width of the streets.

Then, there is a problem that when the wafer is divided by applying a pulsed laser beam of a wavelength having permeability for the wafer to form the deteriorated layer in the inside of the wafer and applying external force along the streets whose strength has been reduced by the formation of the deteriorated layers, a protective film (for example, a SiO₂/SiN/polyimide resin film) covering the front surfaces of devices such as micro-electro-mechanical systems (MEMS) peels off, thereby deteriorating the quality of each device.

### SUMMARY OF THE INVENTION

It is an object of the present invention to provide a wafer dividing method capable of dry dividing a wafer covered by a protective film on the front surfaces of devices without peeling-off the protective film.

To attain the above object, according to the present invention, there is provided a method of dividing a wafer having devices which are formed in a plurality of areas sectioned by a plurality of streets formed in a lattice pattern on the front surface of a substrate and a protective film which covers the front surfaces of the devices into individual devices along the streets, comprising the steps of:

applying a laser beam of a wavelength having absorptivity for the protective film to the protective film from the front surface side of the wafer along the streets to form grooves so as to divide the protective film along the streets;

applying a laser beam of a wavelength having permeability for the substrate to the wafer which has undergone the above protective film dividing step along the streets with its focal point set to positions below the grooves so as to form deteriorated layers in the inside of the substrate along the streets; and

applying external force to the wafer in which the protective film has been divided along the streets and the deteriorated layers have been formed in the inside of the substrate along the streets to divide the wafer along the streets.

According to the present invention, there is also provided a method of dividing a wafer having devices which are formed in a plurality of areas sectioned by a plurality of streets formed in a lattice pattern on the front surface of a substrate and a protective film which covers the front surfaces of the devices into individual devices along the streets, comprising the steps of:

applying a laser beam of a wavelength having permeability for the substrate to the front surface of the wafer with its focal point set to positions below the streets to form deteriorated layers in the inside of the substrate along the streets;

applying a laser beam of a wavelength having absorptivity for the protective film to the protective film from the front surface side of the wafer which has undergone the above deteriorated layer forming step along the streets to form grooves so as to divide the protective film along the streets; and

applying external force to the wafer in which the deteriorated layers have been formed in the inside of the substrate along the streets and the protective film has been divided along the streets to divide the wafer along the streets.

The above deteriorated layer forming step and the above protective film dividing step are carried out while the rear surface of the wafer is adhered to the front surface of a dicing tape affixed to an annular frame, and the wafer dividing step is to apply external force to the wafer by expanding the dicing tape.

According to the wafer dividing method of the present invention, after the step of dividing the protective film for protecting the front surfaces of the devices formed on the substrate of the wafer along the streets and the step of forming the deteriorated layers in the inside of the substrate along the streets, external force is applied to the wafer to divide it along the streets. Therefore, when dividing the wafer along the streets, the protective film does not peel off as it has already been divided along the streets.

### BRIEF DESCRIPTION OF THE DRAWINGS

FIG. 1 is a perspective view of a wafer to be divided by the wafer dividing method of the present invention;

FIG. 2 is an enlarged sectional view of the principal portion of the wafer shown in FIG. 1;

FIG. 3 is a perspective view of the principal portion of a laser beam processing machine for carrying out a protective film dividing step in the wafer dividing method of the present invention;

FIGS. 4(a) and 4(b) are explanatory diagrams showing the protective film dividing step in a first embodiment of the wafer dividing method of the present invention;

FIG. 5 is an enlarged sectional view of the principal portion of the wafer which has undergone the protective film dividing step shown in FIGS. 4(a) and 4(b);

FIG. 6 is a perspective view of the principal portion of a laser beam processing machine for carrying out a deteriorated layer forming step in the wafer dividing method of the present invention;

FIGS. 7(a) and 7(b) are explanatory diagrams showing the deteriorated layer forming step in the first embodiment of the wafer dividing method of the present invention;

FIG. 8 is an enlarged sectional view of the principal portion of the wafer which has undergone the deteriorated layer forming step shown in FIGS. 7(a) and 7(b);

FIG. 9 is a explanatory diagram showing the state that multiple deteriorated layers are formed in laminated structure in the inside of the wafer by the deteriorated layer forming step shown in FIGS. 7(a) and 7(b);

FIGS. 10(a) and 10(b) are explanatory diagrams showing a deteriorated layer forming step in a second embodiment of the wafer dividing method of the present invention;

FIG. 11 is an enlarged sectional view of the principal portion of the wafer which has undergone the deteriorated layer forming step shown in FIGS. 10(a) and 10(b);

FIGS. 12(a) and 12(b) are explanatory diagrams showing a protective film dividing step in the second embodiment of the wafer dividing method of the present invention;

FIG. 13 is an enlarged sectional view of the principal portion of the wafer which has undergone the protective film dividing step shown in FIGS. 12(a) and 12(b);

FIG. 14 is a perspective view of a tape expanding device for carrying out the wafer dividing step in the wafer dividing method of the present invention; and

FIGS. 15(a) and 15(b) are explanatory diagrams showing the wafer dividing step in the wafer dividing method of the present invention.

### DETAILED DESCRIPTION OF THE PREFERRED EMBODIMENTS

Preferred embodiments of the present invention will be below described in detail with reference to the accompanying drawings.

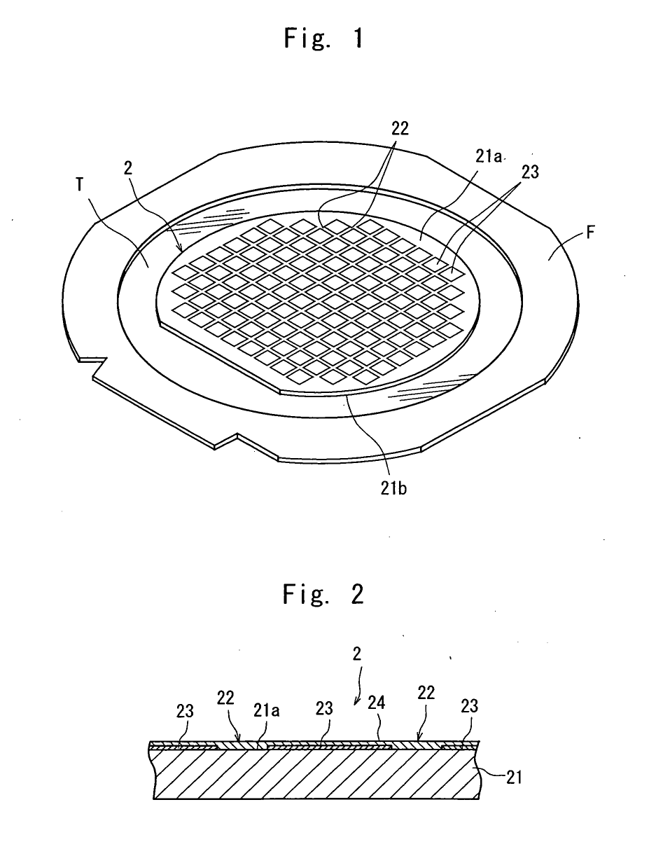

FIG. 1 and FIG. 2 show a wafer to be divided by the wafer dividing method of the present invention. In the wafer 2 shown in FIG. 1 and FIG. 2, a plurality of areas are sectioned by a plurality of streets 22 which are formed in a lattice pattern on the front surface 21a of a silicon substrate 21 and micro-electro-mechanical systems (MEMS) 23 as devices are sectioned in the sectioned areas. A protective film 24 made from SiO₂/SiN/polyimide resin covers the front surface 21a of this wafer 2 as shown in FIG. 2. The rear surface 21b of the wafer 2 constituted as described above is adhered to the front surface of a dicing tape T composed of a synthetic resin sheet made of polyolefin or the like affixed to an annular frame F as shown in FIG. 1 (wafer supporting step).

A first embodiment of the wafer dividing method for dividing the above wafer 2 into individual micro-electro-mechanical systems (MEMS) 23 is described below.

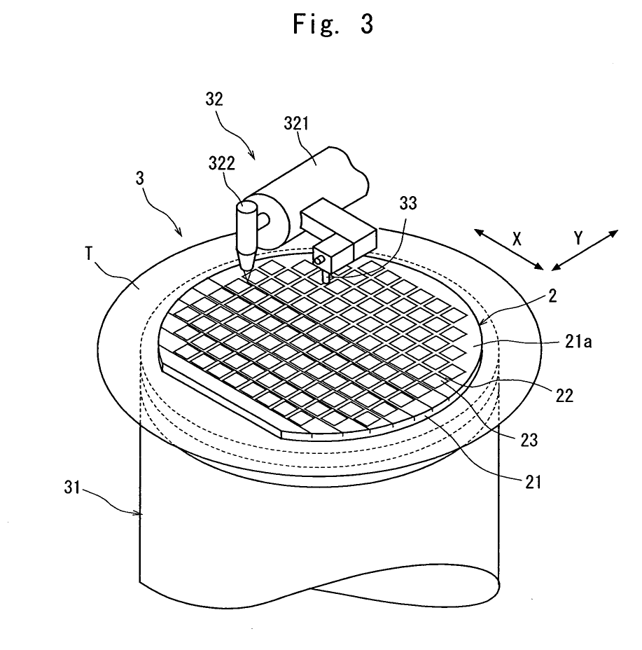

In the first embodiment, first comes the step of applying a laser beam of a wavelength having absorptivity for the protective film 24 to the protective film 24 from the front surface 21a side of the wafer 2 along the streets 22 to form grooves so as to carry out a protective film dividing step to divide the protective film 24 along the streets 22. This protective film dividing step is carried out by using a laser beam processing machine 3 shown in FIG. 3 in the illustrated embodiment. The laser beam processing machine 3 shown in FIG. 3 comprises a chuck table 31 for holding a workpiece, a laser beam application means 32 for applying a laser beam to the workpiece held on the chuck table 31, and image pick-up means 33 for picking up an image of the workpiece held on the chuck table 31. The chuck table 31 is designed to suction hold the workpiece and to be moved in a processing feed direction indicated by an arrow X in FIG. 3 and an indexing feed direction indicated by an arrow Y by an moving mechanism that is not shown.

The above laser beam application means 32 includes a cylindrical casing 321 arranged substantially horizontally. In the casing 321, there is installed a pulsed laser beam oscillation means (not shown) which comprises a pulsed laser beam oscillator composed of a YAG laser oscillator or YVO4 laser oscillator and a cyclic frequency setting means. A condenser 322 for converging a pulsed laser beam oscillated from the pulsed laser beam oscillation means is mounted to the end of the above casing 321. The image pick-up means 33 mounted to the end portion of the casing 321 constituting the above laser beam application means 32 comprises an illuminating means for illuminating the workpiece, an optical system for capturing an area illuminated by the illuminating means and an image pick-up device (CCD) for picking up an image captured by the optical system, and supplies an image signal to a control means that is not shown.

The protective film dividing step which is carried out by using the above laser beam processing machine 3 will be described with reference to FIGS. 3 to 5.

In this protective film dividing step, the dicing tape T adhered to the wafer 2 is first placed on the chuck table 31 of the laser beam processing machine 3 shown in FIG. 3. The wafer 2 is then held on the chuck table 31 through the dicing tape T by activating a suction means that is not shown (wafer holding step). Therefore, the front surface 21a of the wafer 2 held on the chuck table 31 faces up. Although the annular frame F supporting the dicing tape T is not shown in FIG. 3, it is held by a suitable frame holding means provided on the chuck table 31.

The chuck table 31 suction holding the wafer 2 as described above is positioned right below the image pick-up means 33 by the moving mechanism (not shown). After the chuck table 31 is positioned right below the image pick-up means 33, alignment work for detecting the area to be processed of the wafer 2 is carried out by the image pick-up means 33 and the unshown control means. That is, the image pick-up means 33 and the control means (not shown) carry out image processing such as pattern matching to align a street 22 formed in a predetermined direction of the wafer 2 with the condenser 322 of the laser beam application means 32 for applying a laser beam along the street 22, thereby performing the alignment of a laser beam application position. The alignment of the laser beam application position is also carried out on streets 22 formed on the wafer 2 in a direction perpendicular to the above predetermined direction (alignment step).

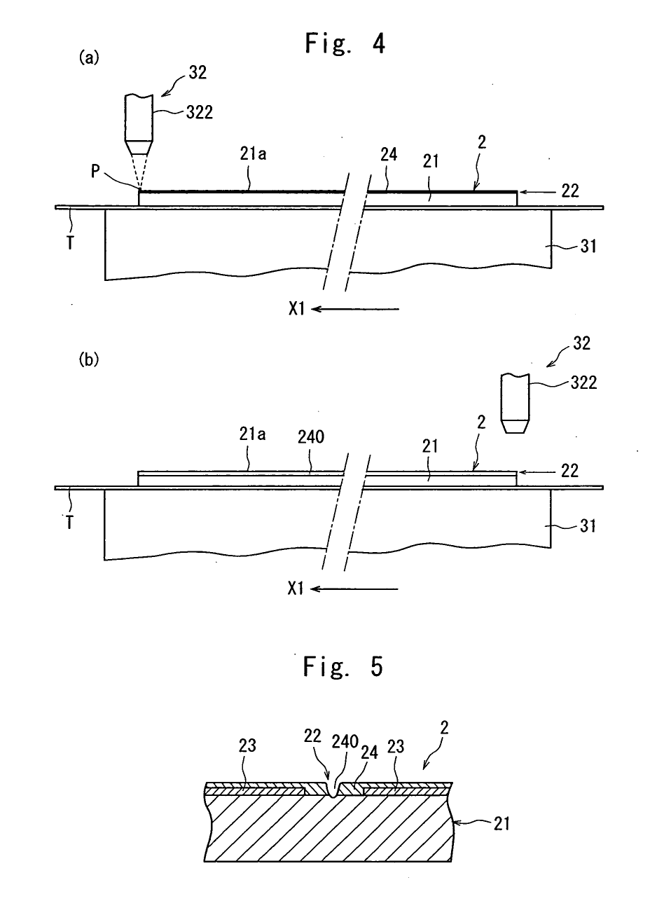

After the alignment of the laser beam application position is carried out by detecting the street 22 formed on the wafer 2 held on the chuck table 31 as described above, the chuck table 31 is moved to a laser beam application area where the condenser 322 of the laser beam application means 32 for applying a laser beam is located as shown in FIG. 4(a) so as to position the predetermined street 22 right below the condenser 322. At this point, the wafer 2 is positioned such that one end (left end in FIG. 4(a)) of the street 22 is located right below the condenser 322 as shown in FIG. 4(a). The chuck table 31 is then moved in the direction shown by the arrow X1 in FIG. 4(a) at a predetermined processing feed rate while a pulsed laser beam of a wavelength having absorptivity for the protective film 24 of the wafer 2 is applied from the condenser 322 of the laser beam application means 32. When the other end (right end in FIG. 4(b)) of the street 22 reaches a position right below the condenser 322 as shown in FIG. 4(b), the application of the pulsed laser beam is suspended and the movement of the chuck table 31 is stopped. In this protective film dividing step, the focal point P of the pulsed laser beam is set to a position near the front surface of the protective film 24 covering the front surface of the wafer 2.

By carrying out the above protective film dividing step, as shown in FIG. 5, a groove 240 reaching the substrate 21 is formed in the protective film 24 along the street 22. As a result, the protective film 24 formed on the street 22 is divided along the street 22 by the groove 240. Although the protective film 24 is processed in this protective film dividing step, it is sublimated right away and the substrate 21 made from silicon is not processed. Therefore, the production of debris is suppressed.

The above protective film dividing step is carried out under the following processing conditions, for example.
Light source of laser beam: LD excited Q switch Nd:YVO4 laser Wavelength: 355 nm
Average output: 1 W
Cyclic frequency: 200 kHz
Focal spot diameter: 5 μm
Processing feed rate: 200 mm/sec
After the above protective film dividing step is carried out along all the streets 22 extending in the predetermined direction of the wafer 2, the chuck table 31 is turned at 90° to carry out the above protective film dividing step along streets 22 extending in a direction perpendicular to the above predetermined direction.

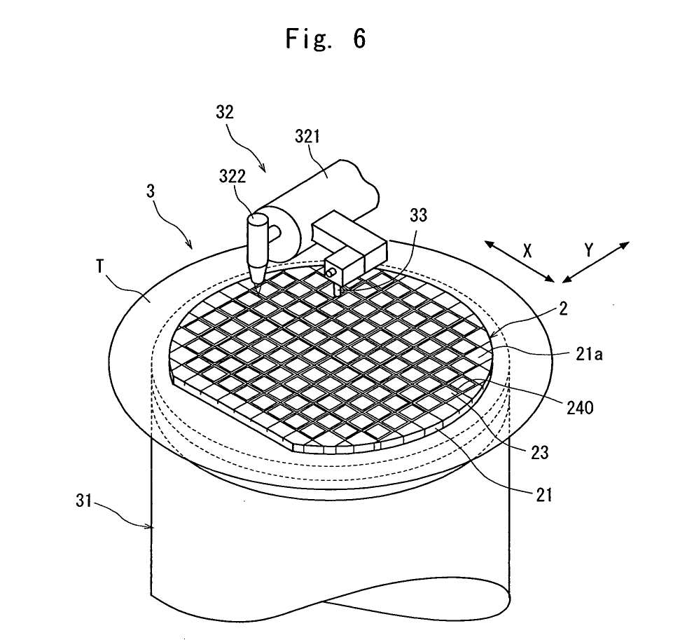

The above protective film dividing step is followed by the step of applying a laser beam of a wavelength having permeability for the substrate 21 along the streets 22 through the grooves 240 to form deteriorated layers in the inside of the substrate 21 along the streets 22. This deteriorated layer forming step is carried out by using a similar laser beam processing machine to the laser beam processing machine 3 shown in FIG. 3 as shown in FIG. 6. Therefore, the constituent members of the laser beam processing machine 3 are given the same reference symbols as in FIG. 3. The laser beam application means 32 comprises a pulsed laser beam oscillation means for oscillating a pulsed laser beam of a wavelength (for example, 1,064 nm) having permeability for the substrate 21.

To carry out the deteriorated layer forming step by using the laser beam processing machine 3 shown in FIG. 6, the dicing tape T adhered to the wafer 2 is placed on the chuck table 31 as shown in FIG. 6. The wafer 2 is held on the chuck table 31 through the dicing tape T by activating the suction means that is not shown (wafer holding step). Therefore, the front surface 21a of the wafer 2 held on the chuck table 31 faces up. Although the annular frame F supporting the dicing tape T is not shown in FIG. 6, it is held by a suitable frame holding means provided on the chuck table 31. The chuck table 31 suction holding the wafer 2 is positioned right below an image pick-up means 33 by cutting feed mechanism that is not shown.

After the chuck table 31 is positioned right below the image pick-up means 33, alignment work for detecting the area to be processed of the wafer 2 is carried out by the image pick-up means 33 and a control means that is not shown as in the above protective film dividing step.

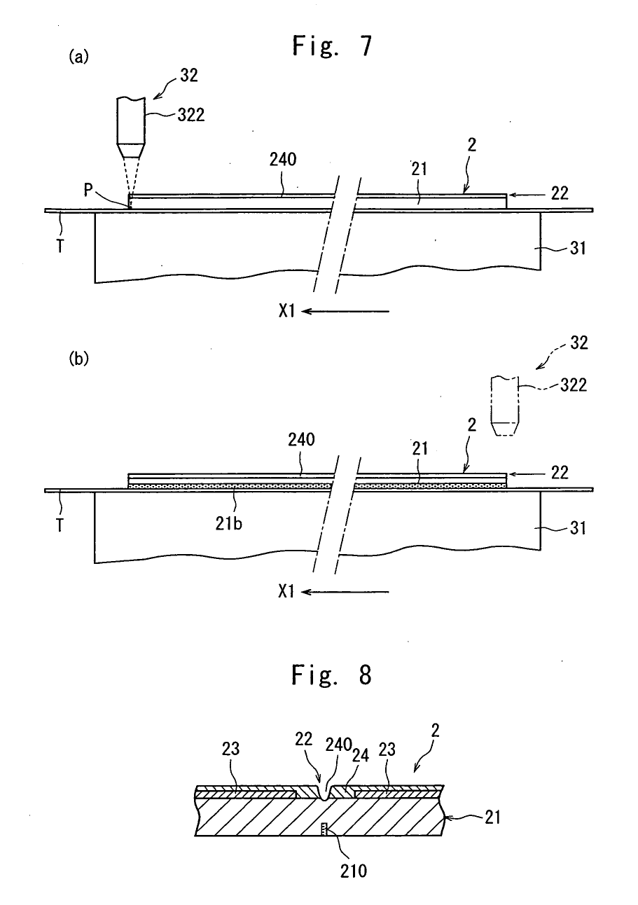

After the alignment work for detecting the area to be processed of the wafer 2 held on the chuck table 31 is carried out as described above, the chuck table 31 is moved to the laser beam application area where the condenser 322 of the laser beam application means 32 for applying a laser beam is located as shown in FIG. 7(a) so as to position one end (left end in FIG. 7 (a)) of the predetermined street 22 (where the groove 240 is formed) right below the condenser 322 of the laser beam application means 32. The chuck table 31 is then moved in the direction indicated by the arrow X1 in FIG. 7(a) at a predetermined processing feed rate while a pulsed laser beam of a wavelength having permeability for the silicon substrate 21 is applied from the condenser 322. When the application position of the condenser 322 of the laser beam application means 32 reaches the other end (right end in FIG. 7(b)) of the street 22 as shown in FIG. 7(b), the application of the pulsed laser beam is suspended and the movement of the chuck table 31 is stopped. In this deteriorated layer forming step, the focal point P of the pulsed laser beam is set to a position near the rear surface 21b (under surface) of the wafer 2. As a result, a pulsed laser beam is applied to the substrate 21 of the wafer 2 with its focal point set to a position below the groove 240, and a deteriorated layer 210 is formed from the rear surface 21b (under surface) toward the inside along the street 22 as shown in FIG. 7(b) and FIG. 8. This deteriorated layer 210 is formed as a molten and re-solidified layer.

The processing conditions in the above deteriorated layer forming step are set as follows, for example.
Light source: LD excited Q switch Nd:YVO4 laser
Wavelength: 1,064 nm
Average output: 2 W
Cyclic frequency: 80 kHz
Focal spot diameter: 1 μm
Processing feed rate: 300 mm/sec

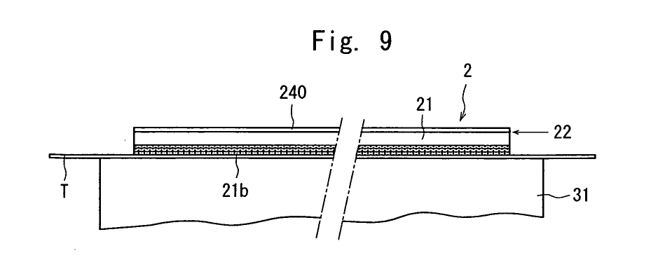

When the wafer 2 is thick, as shown in FIG. 9, the above deteriorated layer forming step is carried out two or more times by changing the focal point P stepwise so as to form plural deteriorated layers 210. For example, as the thickness of the deteriorated layer formed once under the above processing conditions is about 50 μm, the above deteriorated layer forming step is carried out 3 times to form deteriorated layers 210 having a total thickness of 150 μm. In the case of a wafer 2 having a thickness of 300 μm, six layers of deteriorated layer 210 may be formed ranging from the rear surface 21b to the front surface 21a of the substrate 21 of the wafer 2 along the street 22 in the inside of the wafer 2. The deteriorated layer 210 maybe formed only in the inside without exposing to the front surface 21a and to the rear surface 21b of the substrate 21.

After the deteriorated layer forming step is carried out along all the streets 22 extending in the predetermined direction of the wafer 2, the chuck table 31 is turned at 900 to carry out the above deteriorated layer forming step along streets 22 extending in a direction perpendicular to the above predetermined direction.

A description is subsequently given of a second embodiment of the above protective film dividing step and the deteriorated layer forming step.

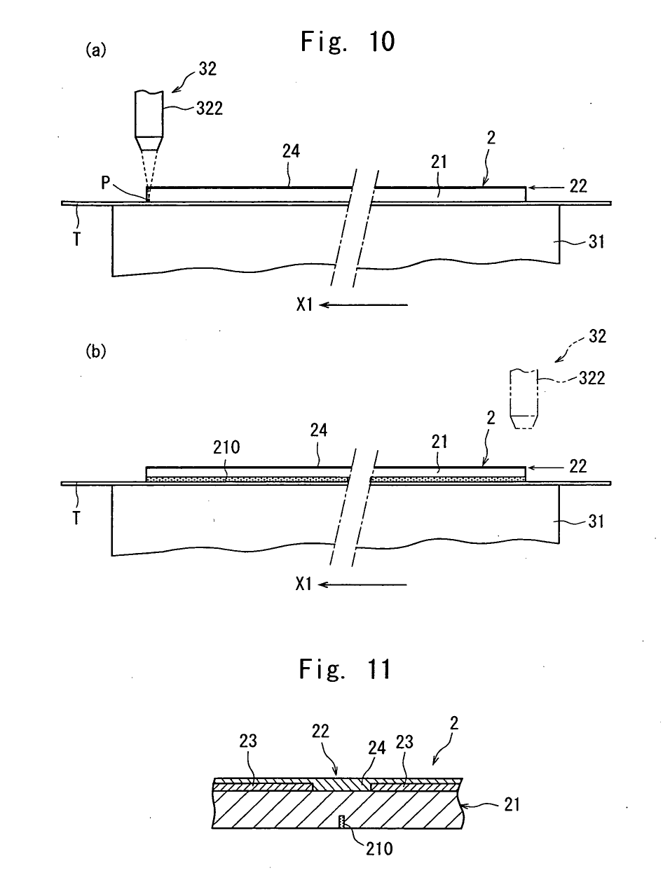

In the second embodiment, first comes the step of applying a laser beam of a wavelength having permeability for the substrate 21 to the front surface 21a of the wafer 2 along the streets 22 to form deteriorated layers in the inside of the substrate 21 along the streets 22. That is, after the above wafer holding step and the alignment step, the chuck table 31 is moved to the laser beam application area where the condenser 322 of the laser beam application means 32 for applying a laser beam is located as shown in FIG. 10(a) so as to position one end (left end in FIG. 10(a)) of a predetermined street 22 (where the groove 240 is formed) right below the condenser 322 of the laser beam application means 32. The chuck table 31 is then moved in the direction indicated by the arrow X1 in FIG. 10(a) at a predetermined processing feed rate while a pulsed laser beam of a wavelength having permeability for the silicon substrate 21 is applied from the condenser 322 with its focal point set to a position below the street 22 as in the deteriorated layer forming step shown in FIGS. 7(a) and 7(b). When the application position of the condenser 322 of the laser beam application means 32 reaches the other end (right end in FIG. 10(b)) of the street 22 as shown in FIG. 10(b), the application of the pulsed laser beam is suspended and the movement of the chuck table 31 is stopped. As a result, a deteriorated layer 210 is formed in the substrate 21 of the wafer 2 along the street 22 as shown in FIG. 10(b) and FIG. 11.

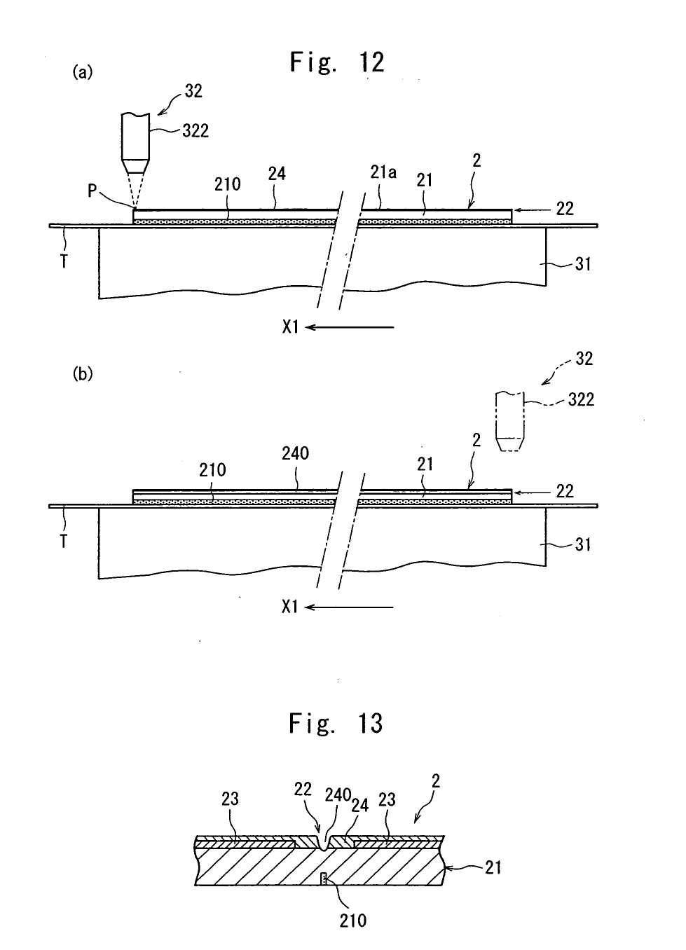

The above deteriorated layer forming step is followed by the step of applying a laser beam of a wavelength having absorptivity for the protective film 24 to the protective film 24 from the front surface 21a side of the wafer 2 to form grooves in the wafer 2 so as to divide the protective film 24 along the streets 22. That is, after the above wafer holding step, the above alignment step and the above deteriorated layer forming step, the chuck table 31 is moved to the laser beam application area where the condenser 322 of the laser beam application means 32 for applying a laser beam is located as shown in FIG. 12 (a) so as to position one end (left end in FIG. 12(a)) of a predetermined street 22 (where the deteriorated layer 210 is formed) right below the condenser 322 of the laser beam application means 32 as shown in FIG. 12(a). The chuck table 31 is then moved in the direction indicated by the arrow X1 in FIG. 12(a) at a predetermined processing feed rate while a pulsed laser beam of a wavelength having absorptivity for the protective film 24 is applied from the condenser 322 as in the protective film dividing step shown in FIGS. 4(a) and 4(b). When the application position of the condenser 322 of the laser beam application means 32 reaches the other end (right end in FIG. 12(b)) of the street 22 as shown in FIG. 12(b), the application of the pulsed laser beam is suspended and the movement of the chuck table 31 is stopped. As a result, a groove 240 reaching the substrate 21 is formed in the protective film 24 along the street 22 as shown in FIG. 12(b) and FIG. 13, and the protective film 24 is divided along the street 22 by the groove 240.

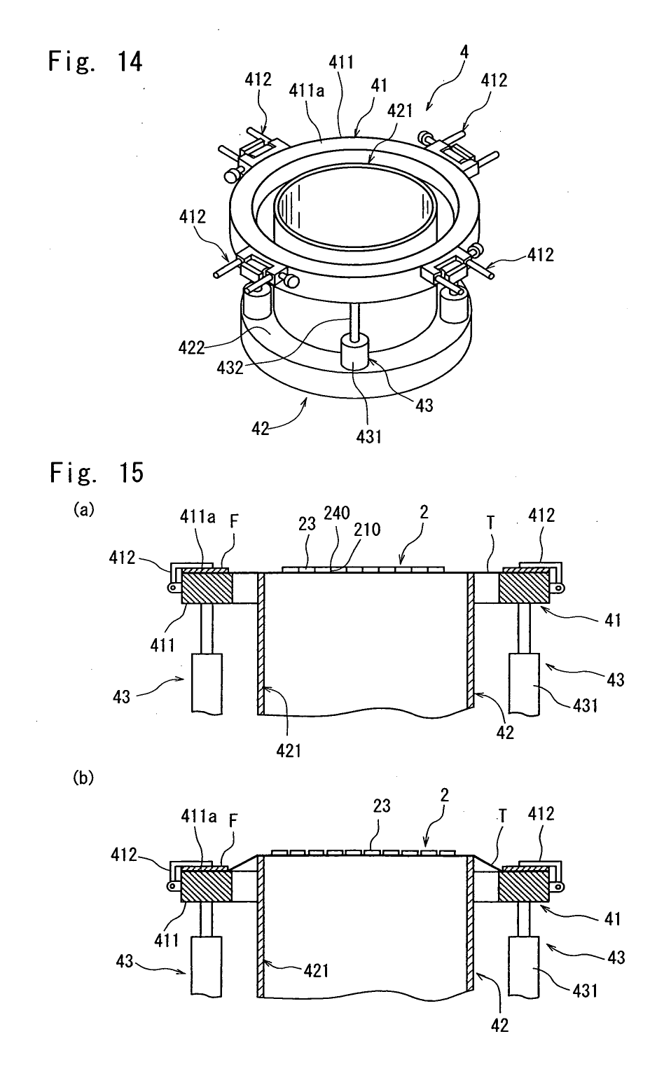

After the above deteriorated layer forming step and the protective film dividing step, next comes a wafer dividing step to divide the wafer 2 along the streets 22 by applying external force to the wafer where the protective film 24 has been divided along the streets 22 and the deteriorated layers have been formed in the inside of the substrate 21 along the streets 22. This wafer dividing step is carried out by using a tape expanding device 4 shown in FIG. 14 in the illustrated embodiment. The tape expanding device 4 shown in FIG. 14 comprises a frame holding means 41 for holding the above annular frame F and a tape expanding means 42 for expanding the dicing tape T affixed to the annular frame F held on the frame holding means 41. The frame holding means 41 comprises an annular frame holding member 411 and a plurality of clamps 412 as fixing means arranged around the frame holding member 411. The top surface of the frame holding member 411 serves as a mounting surface 411a for mounting the annular frame F, and the annular frame F is mounted on this mounting surface 411a. The annular frame F mounted on the mounting surface 411a is fixed on the frame holding member 411 by the clamps 412. The frame holding means 41 constituted as described above is supported by the tape expanding means 42 in such a manner that it can move in the vertical direction.

The tape expanding means 42 comprises an expansion drum 421 installed within the above annular frame holding member 411. This expansion drum 421 has a smaller outer diameter than the inner diameter of the annular frame F and a larger inner diameter than the outer diameter of the wafer 2 on the dicing tape T affixed to the annular frame F. The expansion drum 421 has a support flange 422 at the lower end. The tape expanding means 42 in the illustrated embodiment has a support means 43 which can move the above annular frame holding member 411 in the vertical direction. This support means 43 is composed of a plurality of air cylinders 431 installed on the above support flange 422, and their piston rods 432 are connected to the under surface of the above annular frame holding member 411. The support means 43 composed of the plurality of air cylinders 431 moves the annular frame holding member 411 in the vertical direction between a standard position where the mounting surface 411a becomes substantially flush with the upper end of the expansion drum 421 and an expansion position where the mounting surface 411a is positioned below the upper end of the expansion drum 421 by a predetermined distance. Therefore, the support means 43 composed of the plurality of air cylinders 431 functions as an expanding and moving means for moving the annular frame holding member 411 relative to the expansion drum 421 in the vertical direction.

The wafer dividing step which is carried out by using the tape expanding device 4 constituted as described above will be under described with reference to FIGS. 15(a) and 15(b). That is, the annular frame F supporting the dicing tape T adhered to the rear surface 21b of the wafer 2 (the deteriorated layers 21 are formed in the substrate 21 along the streets 22 and the grooves 240 are formed in the protective film 24) is placed on the mounting surface 411a of the frame holding member 411 constituting the frame holding means 41 and fixed on the frame holding member 411 by the clamps 412 as shown in FIG. 15(a). At this point, the frame holding member 411 is situated at the standard position shown in FIG. 15(a). The annular frame holding member 411 is lowered to the expansion position shown in FIG. 15(b) by activating the plurality of air cylinders 431 as the support means 43 constituting the tape expanding means 42. Therefore, the annular frame F fixed on the mounting surface 411a of the frame holding member 411 is also lowered, whereby the dicing tape T affixed to the annular frame F is brought into contact with the upper edge of the expansion drum 421 and expanded as shown in FIG. 15(b). As a result, since tensile force is applied radially to the wafer 2 adhered to the dicing tape T, the substrate 21 of the wafer 2 is divided into individual micro-electro-mechanical systems (MEMS) 23 along the streets 22 whose strength has been reduced by the formation of the deteriorated layers 210. Since the protective film 24 formed on the front surface of the substrate 21 of the wafer 2 is divided by the grooves 240 formed along the streets 22 at this point, it does not peel off.

What is claimed is:

1. A method of dividing a wafer having devices which are formed in a plurality of areas sectioned by a plurality of streets formed in a lattice pattern on the front surface of a substrate and a protective film which covers the front surfaces of the devices into individual devices along the streets, comprising the steps of:
applying a laser beam of a wavelength having absorptivity for the protective film to the protective film from the front surface side of the wafer along the streets to form grooves so as to divide the protective film along the streets;
applying a laser beam of a wavelength having permeability for the substrate to the wafer which has undergone the above protective film dividing step along the streets with its focal point set to positions below the grooves so as to form deteriorated layers in the inside of the substrate along the streets; and
applying external force to the wafer in which the protective film has been divided along the streets and the deteriorated layers have been formed in the inside of the substrate along the streets to divide the wafer along the streets.

2. The wafer dividing method according to claim 1, wherein the protective film dividing step and the deteriorated layer forming step are carried out while the rear surface of the wafer is adhered to the front surface of a dicing tape affixed to an annular frame, and the wafer dividing step is to apply external force to the wafer by expanding the dicing tape.

3. A method of dividing a wafer having devices which are formed in a plurality of areas sectioned by a plurality of streets formed in a lattice pattern on the front surface of a substrate and a protective film which covers the front surfaces of the devices into individual devices along the streets, comprising the steps of:
applying a laser beam of a wavelength having permeability for the substrate to the front surface of the wafer with its focal point set to positions below the streets to form deteriorated layers in the inside of the substrate along the streets;
applying a laser beam of a wavelength having absorptivity for the protective film to the protective film from the front surface side of the wafer which has undergone the above deteriorated layer forming step along the streets to form grooves so as to divide the protective film along the streets; and
applying external force to the wafer in which the deteriorated layers have been formed in the inside of the substrate along the streets and the protective film has been divided along the streets to divide the wafer along the streets.

4. The wafer dividing method according to claim 3, wherein the deteriorated layer forming step and the protective film dividing step are carried out while the rear surface of the wafer is adhered to the front surface of a dicing tape affixed to an annular frame, and the wafer dividing step is to apply external force to the wafer by expanding the dicing tape.
